(19) United States
(12) Patent Application Publication
(10) Pub. No.: US 2026/0047350 A1
(43) Pub. Date: Feb. 12, 2026

(54) TAPE COMPRISING SUPERCONDUCTING ELEMENTS DISTRIBUTED LONGITUDINALLY

(71) Applicant: SUBRA A/S, Farum (DK)

(72) Inventors: Anders Christian WULFF, Farum (DK); Mette Bybjerg BROCK, Taastrup (DK); Luise Theil KUHN, Fredensborg (DK); Asger Bech ABRAHAMSEN, Roskilde (DK)

(21) Appl. No.: 18/995,586

(22) PCT Filed: Jun. 2, 2023
(86) PCT No.: PCT/EP2023/064858

§ 371 Date: Jan. 16, 2025

(30) Foreign Application Priority Data
Aug. 19, 2022 (EP) 22191251.2

(51) Int. Cl. H10N 60/30; G01J 5/20; G01T 3/08; H10N 60/01; H10N 60/85

(52) U.S. Cl. CPC H10N 60/30; G01J 5/20; G01T 3/08; H10N 60/0548; H10N 60/857; G01J 2005/208

(57) ABSTRACT

A tape includes a plurality of superconducting elements, such as pixels, distributed along a longitudinal direction of the tape. The tape has a size along a first dimension, such as a thickness, which is at least 10 times smaller, than a size along a second dimension, such as a width, and where the size along the second dimension, such as the width, is at least 10 times smaller, than a size along a third dimension, such as a length. There is also presented a use of the tape, a method of manufacture of the tape, and a bolometer and/or a kinetic inductance detector comprising the tape.

### FIELD OF THE INVENTION

The present invention relates to a tape comprising superconducting elements, and more particularly relates to a tape comprising superconducting elements distributed along a longitudinal direction of the tape, and furthermore relates to a use thereof, a method of manufacture thereof, and a bolometer and/or a kinetic inductance detector comprising the tape.

### BACKGROUND OF THE INVENTION

Radiation sensitive elements can be utilized for detection of radiation, such as neutron radiation, which detection may be relevant for numerous purposes, such as detection of neutron radiation, e.g., at a neutron beam facility or a nuclear reactor. However, it would often be advantageous with radiation sensitive elements, which were more sensitive, could withstand higher levels of incoming flux of radiation (such as present in modern day facilities, such as nuclear reactors), and/or which could facilitate better spatial resolution and/or yield spatial resolution from a large area, preferably in a simple manner.

Furthermore, current radiation sensitive elements, such as current radiation sensitive elements yielding spatial resolution from a large area, may require complicated methods of manufacturing and/or methods of manufacturing not realistically applicable for industrial scale manufacturing. It would be advantageous with a radiation sensitive element for which a method of manufacture would be simple and/or would increase an applicability for industrial scale manufacturing, such as be industrially applicable, which were more sensitive and/or could withstand higher levels of incoming flux of radiation.

Hence, an improved radiation sensitive element, which has an improved sensitivity, which could withstand higher levels of incoming flux of radiation, which could facilitate better spatial resolution and/or could yield spatial resolution from a large area, preferably in a simple manner, and/or for which a method of manufacture would be industrially applicable would increase an applicability for industrial scale manufacturing, such as be industrially applicable.

### SUMMARY OF THE INVENTION

It may be seen as an object of the present invention to provide an improved radiation sensitive element, which has improved sensitivity, which could facilitate better spatial resolution, preferably in a simple manner, and/or for which a method of manufacture would increase an applicability for industrial scale manufacturing, such as be industrially applicable. It is a further object of the present invention to provide an alternative to the prior art.

Thus, one or more of the above-described objects and optionally several other objects are intended to be obtained in a first aspect of the invention by providing a tape comprising a plurality of superconducting elements, such as pixels, distributed along a longitudinal direction of the tape, wherein the tape has
a size along a first dimension, such as a thickness, which is at least 10 times smaller, such as at least 100 times smaller, such as at least 1000 times smaller, than a size along a second dimension, such as a width,
   and where
the size along the second dimension, such as the width, is at least 10 times smaller, such as at least 100 times smaller, such as at least 1000 times smaller, than a size along a third dimension, such as a length.

The tape may be useful for detection of radiation, such as neutron radiation. For example, each superconducting element may each serve as a radiation sensitive element, e.g., wherein the superconducting properties may be affected, optionally indirectly, by radiation, and wherein the superconducting properties may in turn be measured and thus allow detecting or measuring said detection. As an example, the tape may be utilized as part of a Transition Edge Sensor (TES), which is understood as is common in the art.

Superconducting Transition Edge Sensors (TES's) can be classified as bolometers, utilizing the transition edge of the superconductor as the method for detecting heat. The transition of a superconductor occurs around the transition temperature (or critical temperature) T_{c} and has a very steep slope, dR/dT. This makes it possible to use it as an ultra-sensitive thermometer.

The invention may be particularly, but not exclusively, advantageous in that by having the superconducting elements on a tape, each superconducting element may be radiation sensitive due the limited thickness of the tape, which may go to reduce a heat capacity of the structure at the position of the superconducting element, such as so that absorption of radiation may increase a temperature to a degree sufficient to change the electrical properties a measurable amount.

Another possible advantage is that by having the superconducting elements distributed along a longitudinal direction of the tape, a good spatial resolution can be achieved in a simple manner since it facilitates measuring radiation at the position of each superconducting element. Thus, by simply placing the tape (i.e., a single structural element, which is spatially extended and optionally flexible) at a position where detection is desirable, multiple, spatially resolved measurements may be facilitated.

Another advantage may be that the tape allows manufacture of the tape, which may increase an applicability for industrial scale manufacturing, such as be industrially applicable, such as realistically industrially applicable. For example, the manufacture of the tape may be carried out via, such as exclusively via, method steps, which are applicable for large scale manufacture and/or is realistically applicable for industrial scale manufacturing. For example, a method of manufacture may be provided, wherein each of the steps of the method of manufacture may be carried out in one or more industrially applicable reel-to-reel setups, etching, deposition, such as dip coating, etc.

A ‘tape’ is understood as an element having the claimed dimensions. It may furthermore be understood that a ‘tape’ is flexible, at least to a certain degree, such as allowing being rolled onto a reel.

‘Superconducting’ is understood as is common in the art, such as the capability of a material to conduct electrical current with substantially zero, such as zero, electrical resistance, optionally when cooled below a characteristic transition temperature (T_{C}). A superconducting material may comprise, such as consist of, rare-earth barium copper oxide (also referred to as REBCO).

The tape may comprise a substrate, such as a substrate whereupon is positioned the superconducting elements.

By ‘substrate’ may be understood ‘a substrate suitable for supporting a superconducting element’ which in turn may be understood as a solid element upon which a superconducting material may be placed, such as deposited, so that the substrate and the superconducting element may together form a superconducting element. The substrate may comprise, such as consist of, one or more metallic elements (such as metals, semi-metals, semi-conductors, and/or metalloids) or alloys. The substrate may comprise, such as consist of, non-metals, such as one or more polymers. The substrate may comprise a substantially planar surface, such as a planar surface. The substrate and the superconducting elements may together form a coated conductor. The substrate may comprise, such as consist of, a composite structure, such as a layered structure. The substrate and superconducting elements may be forming a layered structure comprising one or more superconducting components.

The solid element of the substrate may comprise any material selected from the group comprising: a nickel-based alloy, a copper-based alloy, a chrome based alloy, iron, aluminum, silicon, titanium, tungsten (also known as wolfram (W)), silver, Hastelloy, Inconel®, stainless steel, aluminum and aluminum alloys.

By ‘Hastelloy’ is understood an alloy wherein the predominant alloying ingredient is nickel and wherein other alloying ingredients are added, such as the alloy comprising varying percentages of one or more of, such as all of, the elements: molybdenum, chromium, cobalt, iron, copper, manganese, titanium, zirconium, aluminum, carbon, and tungsten. In a particular embodiment, Hastelloy is an alloy which comprises the elements Ni, Cr, Fe, Mo, Co, W, C. In a more particular embodiment, the alloy also comprises Ni, Cr, Fe, Mo, Co, W, C and one or more of the elements Mn, Si, Cu, Ti, Zr, Al and B. In a more particular embodiment, the alloy is understood to comprise approximately 47 wt percent Ni, 22 wt percent Cr, 18 wt percent Fe, 9 wt percent Mo, 1.5 wt percent Co, 0.6 wt percent W, 0.10 wt percent C, less than 1 wt percent Mn, less than 1 wt percent Si and less than 0.008 wt percent B. Hastelloy may be referred to as “superalloy”or a “high-performance alloy”within the art.

‘Stainless steel’ is generally known in the art. In particular embodiments, there is provided stainless steel with nickel and/or chromium, such as to provide a stainless steel which is corrosion and/or oxidation resistant, mechanically stable and non-magnetic at the operation temperature of the superconducting layer.

The superconducting elements may be part of a coating present on the substrate, such as wherein the coating is comprising a superconducting material, such as a said coating being a multi-layer structure comprising a superconducting material optionally comprising rare-earth barium copper oxide (also referred to as REBCO), or bismuth strontium calcium copper oxide (also referred to as BSCCO), or MgB₂ or NbTi, such as said coating being a superconductor stack, such as said coating being a high-temperature superconductor stack. REBCO could in embodiments be, e.g., YBa₂Cu₃O₇ or GdBa₂Cu₃O₇, or with lower oxygen content, such as YBa₂Cu₃O₇₋ₓ, where x is between 0 and 1.

‘Coating’ is understood as is common in the art, such as a layer, such as a thin layer, of material being applied to a substate. Application of the coating may be carried out in several ways, such as a line-of-sight process, such as anyone of die coating, bubble jet coating, ink jet coating, physical vapor deposition (e.g., pulsed laser deposition and/or sputter deposition), chemical vapor deposition, atomic layer deposition (ALD) and metal organic chemical vapor deposition. The coating may form, optionally with at least a part of the substrate, a 2^{nd} generation high temperature superconducting coated conductor.

The structure and/or texture of the superconducting material in the coating may be endowed to the superconducting layer via the substrate and/or via another layer in the coating, such as a buffer layer.

A ‘buffer (layer)’ is understood as is common in the art and may for example be understood to optionally provide structure, such as crystallographic structure, and/or texture to the superconducting layer and/or may for example be understood to provide an optionally inert chemical barrier. Examples of buffer layers include: Al₂O₃, Y₂O₃, MgO, Gd—Zr—O, LaMnO₃ and SrTiO₃.

By a ‘superconductor stack’ may be understood a layered construction, such as a multi-layer structure, such as a composite structure, optionally with distinct layers, comprising a buffer layer (e.g., 0.1-2 micrometer) and a superconducting layer (e.g., rare-earth-based barium copper oxide (REBCO) of thickness being, e.g., 0.01-5 micrometer). The superconductor stack may be a high-temperature superconductor stack.

‘Radiation’ is generally understood as is common in the art, such as referring to particle radiation (such as neutron radiation, alpha radiation and/or beta radiation) and/or electromagnetic radiation (such as X-ray radiation, gamma radiation, terahertz radiation, infrared radiation and/or visible light radiation). In particular embodiments, ‘radiation’ is understood to refer to neutron radiation.

According to an embodiment, there is presented a tape, wherein the longitudinal direction of the tape is a lengthwise direction of the tape.

According to an embodiment, there is presented a tape, wherein the longitudinal direction of the tape is a parallel with the third dimension.

According to an embodiment, there is presented a tape, wherein the longitudinal direction of the tape is a direction of the tape along it largest dimension. A possible advantage may be that it enables utilizing the largest dimension of the tape for distribution of the superconducting elements, which may thus offer more space (such as 1-dimensional space), e.g., for having more superconducting elements, having more space for each superconducting element, having more space between neighbouring superconducting elements, and/or having more space between most distant superconducting elements.

According to an embodiment, there is presented a tape wherein the first dimension is the dimension in which thickness is measured, the second dimension is the dimension in which width is measured, and the third dimension is the dimension in which length is measured.

According to an embodiment, there is presented a tape, wherein the plurality of superconducting elements (110) are pixels. It may be understood that superconducting material of the superconducting element may itself form a pixel, such as in the form of a meander shaped arrangement of superconducting material, and/or that the superconducting material of the superconducting element together with other one or more other features of the superconducting element (such as a layer of radiation absorbing material and/or a hole in an otherwise surrounding layer) forms the pixel.

‘Pixels’ may be understood as is common in the art, such as discrete elements, such as discrete detecting elements, such as discrete detecting elements of a sensor. The pixels may enable spatially resolved detection, such as 2D or 3D spatially resolved detection, such as enabling detection being spatially resolved along the longitudinal dimension of the tape. In embodiments, each pixel may comprise a structure differing from the surrounding (such as fully encircling) structure of the tape, such as any one of:
a different material composition of the superconducting material, such as a different doping level than a doping level of an adjoining superconducting conductor, or
a difference in one or more adjacent layers to the superconducting material of the superconducting element, such as
   comprising an absorbing layer, such as a radiation absorbing layer, such as a neutron absorbing layer, or
   not comprising a layer being otherwise present adjacent to the pixel, such as encircling the pixel, such as said layer being a metallization layer and/or a protective layer, such as a silver layer.
      Each superconducting element, such as each pixel, may have a size along the longitudinal dimension which is 100 mm or less, such as 75 mm or less, such as 50 mm or less, such as 25 mm or less, such as 10 mm or less, such as 5 mm or less, such as 2 mm or less, such as 1 mm or less.

Each superconducting element, such as each pixel, may have a size along the longitudinal dimension which is less than 50 % of a size of the tape along a third dimension, such as less than 25 % of a size of the tape along a third dimension, such as less than 10 % of a size of the tape along a third dimension, such as less than 1 % of a size of the tape along a third dimension.

An aspect ratio, such as an aspect ratio for dimensions along the second dimension (such as width) and the third dimension (such as length), of the pixel may be less than 10, such as less than 5 such as less than 2.

According to an embodiment, there is presented a tape, wherein the superconducting elements within the plurality of superconducting elements are spatially separated with respect to each other by a finite distance measured in the longitudinal direction, such as a non-zero distance, such as an end-to-end distance between neighbouring superconducting elements being at least 1 nm, such as at least 1 μm, such as at least 10 μm. A spatial separation may be advantageous for enabling electrical separation. It may be understood that the material in the gap between the superconducting elements is not superconducting. A ‘finite distance’ is understood to neither be infinitely small nor infinitely large.

According to an embodiment, there is presented a tape, wherein a dimension of each superconducting element as measured in the longitudinal direction of the tape is less than 10 cm, such as less than 5 cm, such as less than 1 cm, such as less than 5 mm, such as less than 2 mm, such as less than 1 mm.

According to an embodiment, there is presented a tape, wherein a dimension of each superconducting element as measured in the longitudinal direction of the tape is at least 0.1 mm, such as at least 0.5 mm, such as at least 1 mm, such as at least 2 mm.

According to an embodiment, there is presented a tape wherein a distance along the longitudinal direction of the tape between two superconducting elements being most distant with respect to each other is at least 5 mm, such as at least 10 mm, such as more than 10 mm, such as at least 11 mm, such as at least 12 mm, such as at least 13 mm, such as at least 15 mm, such as at least 20 mm, such as at least 30 mm, such as at least 40 mm, such as at least 50 mm, such as at least 100 mm, such as at least 500 mm, such as at least 1 m, such as at least 5 m, such as at least 10 m, such as at least 50 m, such as at least 100 m, such as at least 1 km. By ‘a distance along the longitudinal direction of the tape between two superconducting elements’ may be understood the edge-to-edge distance, such as the shortest distance along the longitudinal direction of the tape from outer periphery of one superconducting element to an outer periphery of another superconducting element. A possible advantage of this embodiment may be that it facilitates, such as facilitates in a simple manner, spatially distributed measurements of radiation, such as measurements distributed across large distances, such as at least corresponding to the distance between the two superconducting elements being most distant with respect to each other. For example, by simply positioning the tape (i.e., a single structural element), optionally in a straight configuration, superconducting elements (i.e., a plurality of superconducting elements) are immediately positioned in a spatially distributed manner. A possible advantage of having said distance (such as a relatively large distance) between two superconducting elements may be that it enables improving accuracy of spatial resolution (for example, by positioning a tape far away from a source of radiation, such as a point source, the angular values of emitted radiation can be determined more precisely while still being able to cover a large angular interval). Signals from each superconducting element may be read-out from the same position or closely placed, such as neighboring, positions (such as via contact pads at an end of the tape), such as the sum of length the electrical signals have to be carried is at least the distance along the longitudinal direction of the tape between the two superconducting elements, in which case it may be particularly advantageous that the tape comprises one or more superconducting conductors, such as HTS conductors, enabling electrically addressing each of the superconducting elements from said position.

According to an embodiment, there is presented a tape, wherein a distance along the longitudinal direction of the tape between two superconducting elements being most distant with respect to each other is at least 50 mm.

According to an embodiment, there is presented a tape, wherein a distance (112) along the longitudinal direction of the tape between two superconducting elements being most distant with respect to each other is at least 1 m.

According to an embodiment, there is presented a tape wherein a nearest neighbor distance along the longitudinal direction of the tape between two superconducting elements is at least 5 mm, such as at least 10 mm, such as at least 50 mm, such as at least 100 mm, such as at least 500 mm, such as at least 1 m, such as at least 5 m, such as at least 10 m, such as at least 50 m, such as at least 100 m, such as at least 1 km. By ‘a nearest neighbor distance along the longitudinal direction of the tape between two superconducting elements’ may be understood the edge-to-edge distance, such as the shortest distance along the longitudinal direction of the tape from outer periphery of one superconducting element to its nearest neighboring superconducting element. A possible advantage of this embodiment may be that it reduces the number and/or the amount of superconducting element material, while still ensuring that superconducting elements are spatially distributed. For example, rather than having all superconducting elements being closely spaced with respect to each other, at least some of the pixels have said minimum nearest neighbor distance, i.e., the same number of pixels can be distributed along a larger length, such as wherein a plurality of superconducting element “pixels” can span a larger length for the same number of electrical connections.

According to an embodiment, there is presented a tape wherein a nearest neighbor distance along the longitudinal direction of the tape between two superconducting elements is less than 1 m, such as less than 50 cm, such as less than 10 cm, such as less than 1 cm, such as less than 5 mm. An advantage is that a higher resolution is achievable and/or that superconducting elements can be packed more densely.

According to an embodiment, there is presented a tape wherein an average nearest neighbor distance along the longitudinal direction of the tape between the superconducting elements is at least 5 mm, such as at least 10 mm, such as at least 50 mm, such as at least 100 mm, such as at least 500 mm, such as at least 1 m, such as at least 5 m, such as at least 10 m, such as at least 50 m, such as at least 100 m, such as at least 1 km. Thus, according to this embodiment, not only is there at least a single pair of superconducting elements having at least said nearest neighbor distance, but the average nearest neighbor distance of all the superconducting elements on the tape is at least the given distance. An advantage may be that it reduces the number and/or the amount of superconducting element material, while still ensuring that superconducting elements are spatially distributed across a relatively large distance.

According to an embodiment, there is presented a tape wherein an average nearest neighbor distance along the longitudinal direction of the tape between the superconducting elements is less than 1 m, such as less than 50 cm, such as less than 10 cm, such as less than 1 cm, such as less than 5 mm. An advantage is that a higher resolution is achievable and/or that superconducting elements can be packed more densely.

According to an embodiment, there is presented a tape wherein the tape is furthermore comprising one or more conductors, such as superconducting conductors, such as HTS conductors, enabling electrically addressing one or more individual superconducting elements from a position spaced apart from each of the one or more individual superconducting elements in a direction along the longitudinal direction of the tape, such as spaced apart in the longitudinal direction by at least 1 cm, such as at least 10 cm, such as at least 1 m, such as at least 10 m, such as at least 100 m, such as at least 1 km. A possible advantage may be that the one or more conductors dispenses with a need for reading out at the site of detection, such as for electrically connecting external equipment (such as measuring probes being external to the tape) to a superconducting element at the position of the superconducting element, such as at the site of detection. This may in turn be advantageous for enabling having, such as having in a simple and/or or well-organized manner, peripheral measuring equipment, such as measuring electronics, in one, single place (e.g., being connected to the end of the one or more conductors, optionally at an end of the tape) and having detection distributed in space. Another possible advantage may be that it enables dispensing with a need to have measuring electronics at the place of detection (which may for example be in harsh conditions, e.g., with high intensity and high-energy neutron radiation, which may be harmful to electronics). An advantage of having the one or more conductors being superconducting conductors, such as HTS conductors, may be particularly pronounced in case of large distances between the position spaced apart from each of the one or more individual superconducting elements and the one or more individual superconducting elements in a direction along the longitudinal direction of the tape.

Each of the one or more conductors may be electrically connected (at one end of the conductor) to a superconducting element (such as a unique superconducting element, such as a unique superconducting element for each conductor) and (at another end of the conductor) the position spaced apart from each of the one or more individual superconducting elements. Each conductor may physically span and electrically connect a path between the superconducting element and the position spaced apart from the superconducting element. This may enable electrically addressing one or more individual superconducting elements from a position spaced apart from each of the one or more individual superconducting elements in a direction along the longitudinal direction of the tape.

The one or more conductors may differ in material properties with respect to the superconducting elements.

According to an embodiment, there is presented a tape wherein each conductor, such as each conductor enabling individually addressing each superconducting element, is superconducting and has a transition temperature:
Within ]275 K; 255 K[, such as ]270 K; 260[, such as 265 K,
Within ]150 K; 170 K[, such as ]155 K; 165 K[, such as 160 K,
Within ]120 K; 140 K[, such as ]125 K; 135 K[, such as 130 K,
Within ]100 K; 120 K[, such as ]105 K; 115 K[, such as 110 K,
Within ]81 K; 101 K[, such as ]86 K; 96 K[, such as 91 K,
Within ]80 K; 100 K[, such as ]85 K; 95 K[, such as 90 K,
Within ]67 K; 87 K[, such as ]72 K; 82 K[, such as 77 K,
Within ]40 K; 60 K[, such as ]45 K; 55 K[, such as 50 K,
Within ]20 K; 40 K[, such as ]25 K; 35 K[, such as 30 K,
Within ]10 K; 30 K[, such as ]15 K; 25 K[, such as 20 K,
Within ]2.2 K; 6.2 K[, such as ]3.2 K; 5.2 K[, such as 4.2 K,
Within ]1 K; 3 K[, such as ]1.5 K; 2.5 K[, such as 2 K, or
Within ]10 K; 1 K[, such as ]50 mK; 200 mK[, such as 100 mK.

According to an embodiment, there is presented a tape wherein each conductor, such as each conductor enabling individually addressing each superconducting element, is superconducting and has a transition temperature being different from a transition temperature of each of the superconducting elements. A difference in transition temperature (T_{c}) between each superconducting element and each conductor, may be at least 0.1 K, such as at least 1 K, such as at least 10 K, such as at least 20 k, such as at least 50 k. A transition temperature of each conductor may be higher than a transition temperature of each superconducting element. In an embodiment, a transition temperature of each superconducting element is within the range [0 K; 50 K], such as within the range [10 K; 30 K], such as 20 K, and/or a transition temperature of each conductor is within the range [60 K; 120 K], such as within the range [80 K; 100 K], such as 90 K.

According to an embodiment, there is presented a tape wherein each conductor, such as each conductor enabling individually addressing each superconducting element, is superconducting and has a transition temperature being different from a transition temperature of each of the superconducting elements, wherein each superconducting element forms a coherent superconducting structure with a (corresponding) conductor. By ‘coherent’ element may be understood a physically connected element without internal interface, such as a change (such as an abrupt change) in material properties, such as a change in crystal structure. Such superconducting structure may be realized by originally having a superconducting structure with homogenous transition temperature and then changing the transition temperature of the (part of the superconducting structure corresponding to, respectively) the superconducting element and the conductor. Changing transition temperature may be done in a number of ways, e.g., by doping and/or removal of oxygen (which may each be done in a spatially selective manner). Providing originally such a coherent element with homogeneous transition temperature may be advantageous for providing a simple and/or efficient production process.

According to an embodiment, there is presented a tape, wherein the tape is furthermore comprising for each superconducting element a contact pad, such as each contact pad being separate from and electrically connected to the corresponding superconducting element, such as electrically connected via a conductor on the tape, such as with no distance between the tape (or the remainder of the tape) and the conductor, such as wherein the plurality of contact pads enables electrically accessing each superconducting element individually via the contact pads by positioning the tape in a socket with terminals electrically contacting the contact pads. This may be advantageous for establishing an electrical connection between peripheral equipment and the superconducting elements without physically connecting the peripheral equipment directly to the superconducting elements.

According to an embodiment, there is presented a tape wherein a transition temperature of one or more of the superconducting elements is:
Within ]275 K; 255 K[, such as] 270 K; 260[, such as 265 K,
Within ]150 K; 170 K[, such as ]155 K; 165 K[, such as 160 K,
Within ]120 K; 140 K[, such as ]125 K; 135 K[, such as 130 K,
Within ]100 K; 120 K[, such as ]105 K; 115 K[, such as 110 K,
Within ]81 K; 101 K[, such as ]86 K; 96 K[, such as 91 K,
Within ]80 K; 100 K[, such as ]85 K; 95 K[, such as 90 K,
Within ]67 K; 87 K[, such as ]72 K; 82 K[, such as 77 K,
Within ]40 K; 60 K[, such as ]45 K; 55 K[, such as 50 K,
Within ]20 K; 40 K[, such as ]25 K; 35 K[, such as 30 K,
Within ]10 K; 30 K[, such as ]15 K; 25 K[, such as 20 K,
Within ]2.2 K; 6.2 K[, such as ]3.2 K; 5.2 K[, such as 4.2 K,
Within ]1 K; 3 K[, such as ]1.5 K; 2.5 K[, such as 2 K, or
Within ]0 K; 1 K[, such as ]50 mK; 200 mK[, such as 100 mK.

‘Transition temperature’ (T_{C}) is understood as is common in the art, such as the temperature at which the transition from normal state to superconducting state takes place upon cooling with zero applied magnetic field of the superconducting elements and at a pressure of 1 atmosphere. In case the transition takes place across a finite temperature range, such as a temperature range, spanning a temperature difference commonly referred to as ΔT_{C}, the transition temperature may be defined as the middle temperature value of the range (such as ½*ΔT_{C} from both endpoints of the range) and/or as the point on the R(T) curve having the highest (optionally global) value of dR/dT. The transition temperature may elsewhere be referred to as the critical temperature.

According to an embodiment, there is presented a tape wherein the plurality of superconducting elements distributed along a longitudinal direction of the tape is 4 or more, such as 5 or more, such as 10 or more, such as 50 or more, such as 100 or more, such as 500 or more, such as 1000 or more, such as 10000 or more. An advantage of this may be that the tape enables measuring at a corresponding number as the number of superconducting elements, such as wherein a single tape facilitates measuring at a relatively high number of spatially distributed positions.

According to an embodiment, there is presented a tape, wherein the plurality of superconducting elements (110) distributed along a longitudinal direction of the tape is 5 or more.

According to an embodiment, there is presented a tape, wherein the plurality of superconducting elements (110) distributed along a longitudinal direction of the tape is 50 or more.

According to an embodiment, there is presented a tape, wherein each superconducting element is suitable for detection of radiation, such as particle radiation (such as neutron radiation, alpha radiation and/or beta radiation) and/or electromagnetic radiation (such as X-ray radiation, gamma radiation, terahertz radiation, infrared radiation and/or visible light radiation).

‘Suitable for detection of radiation’ may be understood to include a capability of withstanding radiation, such as wherein material properties, such as T_{C} and/or J_{c}, remains stable, such as deviates for at most 10 %, such as at most 5 %, such as at most 1 %, from their original value, upon being subjected to irradiation with an average flux of 10⁸ neutrons (such as neutrons having an average energy in the range 1-20 MeV, such as an average energy of 1 MeV) pr. cm² pr. second for at least 24 hours, such as a least 50 hours, such as a least 100 hours, such as a least 500 hours, such as at least 1000 hours.

By ‘suitable for detection of radiation’ may additionally or alternatively be understood that radiation may be detected in a temporally resolved manner, such as a capability of detecting an average flux of 10⁸ neutrons pr. cm² pr. second, within a measurement period of time of 24 hours, such as within 1 hour, such as within 1 minute, such as within 1 second, such as within 100 ms (milliseconds), such as within 10 ms, such as within 1 ms, such as within 100 μs (microseconds), such as within 10 μs, such as within 1 μs, such as within 100 ns (nanoseconds), such as within 10 ns, such as within 1 ns. For example, if a there is an average flux of 10⁸ neutrons pr. cm² pr. second onto a superconducting element of the tape, then it should be measurable within said measurement period of time.

According to an embodiment, there is presented a tape, wherein the tape comprises:
a substrate, and
a radiation absorbing layer.

By ‘radiation absorbing layer’ may be understood a layer applied to the superconducting element, which enables that a measurement of radiation via a measurement of the electrical properties of the superconducting element to have improved sensitivity, such as yielding a larger change in an electrical property for an incident radiation, such as neutron radiation, compared to a situation where the radiation absorbing layer is absent. A thickness (such as a size along the first dimension) may be at most 10 μm, such as at most 8 μm, such as at most 6 μm, such as at most 4 μm, such as at most 2 μm, such as at most 1 μm. A thickness (such as a size along the first dimension) may be at least 10 nm, such as at least 100 nm, such as at least 1 μm. A potential advantage of a radiation absorbing layer is increased lifetime of the tape.

According to an embodiment, there is presented a tape, wherein the tape comprises:
a substrate,
one or more superconducting elements covered with a first type of radiation absorbing layer, and
one or more superconducting elements
   covered with a second type of radiation absorbing layer, with the first type of radiation absorbing layer being different with respect to the first type of radiation absorbing layer, or
   having the direct access to the surroundings, such as not covered with a radiation absorbing layer.

A possible advantage of this embodiment may be that it enables measuring different types of radiation, and/or that some superconducting elements may yield signals, which can be useful for interpretation of signals from other superconducting elements (such as in case of taking into account, such as deducting, background radiation).

‘Sensitivity’ is understood as is common in the art, such as the slope of an output characteristic curve (DY/DX), such as the ratio between a change ‘DY’ of an output ‘Y’ (such as DY being a measure of a change of a measured resistance Y) and a change ‘DX’ of an input ‘X’ (such as a DX being a measure of a change of measured incident radiation X). It is generally understood that an “improved” sensitivity, such as in a detector that employs a TES, is given by a larger slope.

According to an embodiment, there is presented a tape wherein the substrate is positioned opposite the radiation absorbing layer with respect to the plurality of superconducting elements, such as the plurality of superconducting elements being sandwiched between the substrate and the radiation absorbing layer.

It is conceivable and encompassed that the sandwich construction merely refers to the positions in a dimension orthogonal to the (at least local) plane of the substrate, i.e., there may be no straight line orthogonal to the substrate and intersecting each of the radiation absorbing layer, the superconducting element and the substrate. For example, in an embodiment, there is a straight line parallel to the substrate, which intersects the radiation absorbing layer and the superconducting element, but not the substrate. This may for example be the case where a part of the substrate has been removed, e.g., to improve the thermal properties of the tape surrounding a superconducting element. In a specific example, there may additionally be a radiation absorbing layer on each side of the superconducting element (wherein the substrate is not between the radiation absorbing layers).

It is generally understood that ‘plane’ of the tape (and/or substrate) is understood to refer to ‘local plane’ in case the tape (and/or substrate) is bend, such as the ‘local plane’ being a plane being, e.g., tangential at a given position (wherein the tape may be non-planar at said position and/or at other positions) of the tape, such as at the position, such as the center of gravity, of a superconducting element.

In an embodiment there is a plurality of superconducting elements on each side of the substrate (such as with respect to a plane of the substrate) and optionally wherein the tape is furthermore comprising a radiation absorbing layer on one or both sides of the substrate, wherein the substrate is in each case positioned opposite the radiation absorbing layer with respect to the plurality of superconducting elements (on that side), such as the plurality of superconducting elements (on that side) being sandwiched between the substrate and the radiation absorbing layer. In case of radiation absorbing layers on each side, the substrate will in this case be placed between the radiation absorbing layers.

According to an embodiment, there is presented a tape wherein the tape comprises a radiation absorbing layer, and wherein the radiation absorbing layer comprises, such as comprises at least 10 % w/w, such as substantially consists of, such as consists of, one or more of ³He, ⁶Li, ¹⁰B, ¹⁵⁷Gd and ¹¹³Cd. This may be advantageous for yielding a high absorption cross-section with respect to neutron radiation, such as a high absorption cross-section with relatively little material. A high absorption cross-section may in turn yield a high sensitivity. In one embodiment a high absorption cross-section may yield a higher detector sensitivity due to the local heat generated in the absorbing layer which is in turn transferred to the superconducting circuit, such as the superconducting meander pattern, and measured as an increase in resistivity of the said superconducting meander, or part hereof.

According to an embodiment, there is presented a tape wherein the tape comprises a radiation absorbing layer, and wherein the radiation absorbing layer comprises, such as comprises at least 10 % w/w, such as substantially consists of, such as consists of, one or more of gold (Au) (such as gold and chromium (Au+Cr)), bismuth (Bi) (such as bismuth-cupper (BiCu) or bismuth-gold (BiAu)), and tin (Sn) This may be advantageous for yielding a high absorption cross-section with respect to X-ray radiation, such as a high absorption cross-section with relatively little material. A high absorption cross-section may in turn yield a high sensitivity.

According to an embodiment, there is presented a tape wherein each superconducting element is individually electrically addressable, optionally at least partially via a conductor, such as a conductor being superconducting, with respect to the other superconducting elements, such as enabling spatially resolving in a longitudinal direction of the tape radiation incident on the tape. Each superconducting elements, such as each superconducting element, may be electrically accessible due to the tape comprising one or more, optionally superconducting, conductors positioned in or on a surface plane of the tape and/or a substrate of the tape (which plane may be coincident with a plane of the superconducting elements and/or wherein a material of the conductors is similar or identical with a material of the superconducting elements). According to one example each superconducting element is electrically accessible via a conductor on one side of the superconducting element and another conductor at another side (such as the sides being distanced from each other in a direction in the plane of the tape and orthogonal to the longitudinal direction of the tape) and the electrical properties of that specific superconducting element can be probed via the conductors, optionally at an end of the tape. According to an other example, all superconducting elements are connected at one side to a common conductor, such as a grounded conductor, and the other side of each superconducting element is connected to a dedicated conductor. According to this other example, each superconducting element can be electrically probed through the common conductor and the dedicated conductor. An advantage of having the superconducting elements being individually electrically accessible is that they can be electrically probed individually, which may in turn enable spatially distributed detection, optionally from one or more spatially different points, such as from the end of the tape.

Each superconducting element may be individually electrically addressable due to the tape comprising one or more conductors being electrically connected (at one end of the conductor) to a superconducting element (such as a unique superconducting element, such as a unique superconducting element for each conductor) and (at another end of the conductor) a position spaced apart from each of the one or more individual superconducting elements.

According to an embodiment, there is presented a tape wherein each superconducting element comprises at least a portion, such as a superconducting material, shaped in a meander pattern. ‘Meander shape’ is understood as is common in the art. An advantage of this may be that a certain input may yield a greater output, such as an increase in sensitivity.

The meander structure may be a (double) serpentine meander structure or a (double) spiral, such as a rectangular spiral.

According to an embodiment, there is presented a tape, wherein the superconducting elements each comprise a meander structure, such as a meander structure of superconducting material, wherein a dimension, such as a width, such as a line width, of a line within the meander structure along the first dimension and/or the second dimension, is within [1 μm; 100 μm], such as within [20 μm; 50 μm]. This may be beneficial for detection sensitivity and/or lifetime.

According to an embodiment, there is presented a tape, wherein the superconducting elements each comprise a meander structure, such as a meander structure of superconducting material, wherein a dimension, such as a thickness, of the meander structure along the first dimension, is within [50 nm; 5 μm], such as within [50 nm; 3 μm]. This may be beneficial for detection sensitivity and/or lifetime.

According to an embodiment, there is presented a tape, wherein each superconducting element is a high-temperature superconducting element. ‘High-temperature superconducting’, often abbreviated “HTS” or “high-Tc”, is understood as is common in the art, such as the capability of a material to be superconducting above a temperature of above 30 K, such as above 77 K.

According to an embodiment, there is presented a tape wherein the tape can be bent, such as bent without breaking or rupturing, such as elastically bent, so that a radius of curvature becomes less than 1 m, such as less than 50 cm, such as less than 25 cm, such as less than 10 cm, such as less than 5 cm, such as less than 30 mm, such as less than 25 mm, such as less than 20 mm, such as less than 10 mm, such as less than 5 mm, such as so that a radius of curvature changes between a region of less than 10 mm, such as less than 5 mm, and, such as to or from, a region being more than 100 mm, such as more than 1 m. An advantage of this may be that the tape may be bent (or shaped) so as to be stored in less space, such as in a reel and/or that the tape may be spatially adapted to certain applications, e.g., bent to conform to the interior surface of a nuclear reactor or to the outside surface of an artificial satellite. Another possible advantage may be that the tape is less brittle and/or becomes less prone to breaking, e.g., due to the ability to be bent causes the tape rather to bend than break under the influence of an applied force. The ability to bend may be given by employing sufficiently thin and/or sufficiently flexible materials for the manufacture of the tape.

According to an embodiment, there is presented a tape, wherein the tape can be bent, such as bent without breaking or rupturing, such as elastically bent, so that a radius of curvature becomes less than 20 mm.

According to an embodiment, there is presented a tape, wherein the plurality of superconducting elements comprises superconducting elements distributed along a direction being orthogonal to the longitudinal direction of the tape, such as enabling spatially resolving in at least two dimensions radiation incident on the tape. An advantage may be that this may give more data for each point along the longitudinal direction, e.g., enabling averaging values from multiple superconducting elements at a longitudinal position. Another possible advantage may be that having multiple superconducting elements at a longitudinal position may increase a likelihood that a measurement can be conducted for the longitudinal position, e.g., in case one superconducting element breaks down, then another superconducting element at the same longitudinal position can be probed. Another possible advantage may be that a two-dimensional spatial resolution can be achieved from a single tape.

According to an embodiment, there is presented a tape, wherein one or more of the superconducting elements within the plurality of superconducting elements defines a plane which is non-parallel (such as tilted), such as is angled with at least 1°, such as angled with at least 5°, such as angled with at least 10°, such as angled with at least 20°, such as angled with at least 30°, such as angled with at least 40°, such as angled with at least 45°, such as angled with at least 60°, such as angled with at least 75°with respect to a plane of the tape, such as with respect to a plane defined by a portion of the tape being adjacent, such as adjoining, each of the one or more superconducting elements. A possible advantage may be that it enables changing, such as increasing, a path length of radiation through the one or more of the superconducting elements (and optionally through an absorption layer positioned thereon, if present), which may in turn go to increase sensitivity (assuming the same amount of radiation is incident). Another possible advantage may be that the sensitivity may be increased by the orientation of the superconducting element (and optionally of an absorption layer positioned thereon, if present) being changed so as to enable a larger amount of radiation to be incident on the superconducting element (and optionally of an absorption layer positioned thereon, if present). For example, the orientation may be changed to decrease the smallest angle between a normal vector (or a vector being anti-parallel with the normal vector) of the superconducting element (and optionally of an absorption layer positioned thereon, if present) and a direction of incoming radiation.

According to an embodiment, there is presented a tape wherein the tape comprises a substrate and wherein the substrate comprises protrusions, through-going holes and/or pillars at the positions of the superconducting elements, optionally with undercuts. Such protrusions, through-going holes and/or pillars may be realized, e.g., via cold rolling, etching and/or deposition during manufacturing. A possible advantage may be that it improves the thermal properties of the tape surrounding a superconducting element (such as for reducing heat conduction away from the superconducting element, so that a larger portion of energy absorbed from radiation goes into increasing a temperature of the superconducting element, which in turn yields an improved sensitivity). An effect of the protrusions, through-going holes and/or pillars may be that a heat conduction away from the superconducting elements is smaller with respect to a situation without the protrusions, through-going holes and/or pillars, such as a situation wherein the superconducting elements are positioned on a surface of the tape being flush with the remainder of the tape surface (such as wherein the surface portions of the tape at the superconducting elements form a single smooth, such as planar, surface together with the adjacent, such as adjoining, such as surrounding, portions of the surface of the tape) and wherein the tape, at least at the position of the superconducting element, is substantially a rectangular cuboid, such as a rectangular cuboid (such as having no pillars, no through-going holes and no protrusions).

According to an embodiment, there is presented a tape, wherein the tape comprises a substrate (108) and wherein the substrate comprises
protrusions with undercuts, and/or
pillars with undercuts (1426)
   at the positions of the superconducting elements (110). A possible advantage of undercuts may be that it enables simplifying production because the undercuts may serve to ensure physical separation between material deposited on each of the sides of the undercut. Another advantage may be that if separation is achieved via undercuts, then a step of separation via, e.g., scribing is rendered superfluous, which may in turn also dispense with a negative effect on the properties of the remaining superconducting material, e.g., associated with scribing, may be avoided. Another possible advantage may be that the undercuts may serve to diminish heat conduction through the protrusions and/or the pillars.

According to an embodiment, there is provided a tape wherein superconducting elements are present with different absorbing layers (and optionally also one or more superconducting elements with no absorbing layers). This may be advantageous for enabling a combination detector, e.g., for space applications and/or neutron scattering applications, which can detect one or more of: neutron radiation, IR radiation, alpha radiation, etc. For example, it could be advantageous to have a combination with both neutron radiation sensitive absorbing layer on one set of one or more superconducting elements and gamma radiation sensitive (latter is unavoidable) on another set of one or more superconducting elements, such as just one pixel just being gamma radiation sensitive.

According to a second aspect of the invention, there is presented a bolometer and/or a kinetic inductance detector comprising the tape according to the first aspect. A ‘bolometer’ is understood as is common in the art, such as a device for measuring radiant heat by means of a material having a temperature-dependent electrical resistance. A ‘kinetic inductance detector’ is understood as is common in the art, such as a detector detecting photons by photon absorption (such as microwave radiation) breaking Cooper pairs and thereby increasing kinetic inductance.

According to a third aspect of the invention, there is presented a system comprising:
A tape according to the first aspect, wherein the tape is furthermore comprising for each superconducting element a contact pad, and
A socket comprising a plurality of terminals,
   wherein the plurality of contact pads enables electrically accessing each superconducting element individually via the contact pads by positioning the tape in the socket with the terminals electrically contacting the contact pads.

The plurality of contact pads may enable electrically accessing each superconducting element individually via the contact pads due to the contact pads and the socket, such as the terminals of the socket, being arranged in a manner, such as arranged geometrically similarly, so that upon positioning the tape in the socket, each contact pad makes physical and electrical contact with a terminal of the socket.

An advantage of this system may be that it facilitates reading out electrical properties of each of the plurality of superconducting elements in a simple and/or robust manner.

According to an alternative aspect, there is presented a system comprising:
A tape according to the first aspect, and
A cryostat,
   where the tape is comprised within the cryostat.

‘Cryostat’ is understood as is common in the art, such as an apparatus for maintaining a temperature lower, such as much lower, than the surroundings, such as below 273 K. In embodiments the cryostat may comprise at least a window being transmissible to radiation, such as transmissible to radiation during use, such as when maintaining a temperature sufficiently low for the purpose of keeping the superconducting elements of the temperature below T_{c}, and/or around T_{c}, such as at T_{c}. For example, the cryostat can be made wholly or partially, such as at least comprising a window, made of aluminum, such as with a thickness of 3 mm, which would effectively be transparent to neutron radiation. An advantage would be that this system could be used for detection of neutron radiation at relatively low intensities. In embodiments the cryostat may comprise at least a window being at least partially shielding to radiation, such as at least partially shielding to radiation during use, such as when maintaining a temperature sufficiently low for the purpose of keeping the superconducting elements of the temperature below T_{c}, and/or around T_{c}, such as at T_{c} For example, the cryostat can be made wholly or partially, such as at least comprising a window comprising ¹⁰B, such as in a thin layer, which would partially shield against neutron radiation. An advantage would be that this system could be used for detection of neutron radiation at relatively high intensities.

According to further alternative aspects, there is presented a system comprising a tape according to the first aspect and any one of:
A particle accelerator, such as a high energy particle accelerator, such as wherein the tape is arranged for enabling monitoring or detecting neutron flux in an area where continuous neutron flux monitoring or detecting is required,
A nuclear reactor, such as a nuclear fusion reactor or a nuclear fission reactor, where the tape is optionally positioned in or at a sub-shield of the nuclear reactor,
A magnet coil comprising tape, such as for the purpose of magnet protection,
A neutron facility, such as wherein the tape is arranged for enabling monitoring or detecting neutron flux at a target station of the neutron facility, such as wherein the neutron facility is a large-scale neutron facility, or
A space-instrument, such as an artificial satellite, such as wherein the tape is arranged for monitoring or detecting cosmic infra-red radiation.

‘Detecting’ is understood to encompass both binary detection, such as merely qualitatively detecting the presence (yes/no) of a certain minimum amount of radiation, and quantitative measuring, such as wherein an amount of radiation is quantified. In embodiments, detecting is understood as quantitatively measuring.

According to a fourth aspect of the invention, there is presented use of a tape according to the first aspect, a bolometer and/or a kinetic inductance detector according to the second aspect and/or a system according to any of the third aspect, the alternative aspect and/or any of the further alternative aspects for detection, such as spatially resolved detection, of radiation, such as neutron radiation, terahertz radiation, infrared radiation and/or visible light radiation. According to embodiments, the tape according to the first aspect may be used for
monitoring or detecting neutron flux in or at a particle accelerator, such as in an area where continuous neutron flux monitoring or detecting is required,
monitoring or detecting neutron flux in a sub-shield of a nuclear reactor,
monitoring or detecting neutron flux at a target station of a neutron facility, such as a large-scale neutron facility, or
monitoring or detecting infra-red radiation, such as cosmic infra-red radiation, at a space-instrument, such as an artificial satellite.

According to a fifth aspect of the invention, there is presented a method of providing a tape according to the first aspect, a bolometer and/or a kinetic inductance detector according to the second aspect and/or a system according to any of the third aspect, the alternative aspect and/or any of the further alternative aspects, said method comprising:
Depositing the plurality of superconducting elements, such as depositing on a substrate.

According to an embodiment, there is presented a method further comprising any one or more of the steps of:
Providing a substrate, wherein the depositing the plurality of superconducting elements, comprising depositing the plurality of superconducting elements on the substrate, and optionally topographically modifying the substrate optionally prior to depositing the plurality of superconducting elements.
Depositing a radiation absorbing layer on the plurality of superconducting elements,

According to an embodiment, there is presented a method further comprising:
Depositing one or more conductors, such as superconducting conductors, such as HTS conductors, enabling electrically addressing one or more individual superconducting elements from a position spaced apart from each of the one or more individual superconducting elements in a direction along the longitudinal direction of the tape, such as spaced apart in the longitudinal direction by at least 1 cm, such as at least 10 cm, such as at least 1 m, such as at least 10 m, such as at least 100 m, such as at least 1 km.

According to an embodiment, there is presented a method wherein the one or more conductors comprise superconducting material, and wherein
depositing the superconducting material of the superconducting elements (110) and depositing superconducting material of the one or more conductors is carried out in a first step, optionally with the superconducting material of the superconducting elements and the superconducting material of the one or more conductors being similar, such as substantially identical, such as identical,
in a second step being subsequent to the first step, one or both of
   i. the superconducting material of the superconducting elements, and
   ii. the superconducting material of the one or more conductors, is treated (such as via doping or removal of oxygen, such as via different levels of doping or removal of oxygen for the superconducting elements and the conductors) so as to increase and/or introduce a difference in transition temperature, between
   i. a transition temperature of the superconducting material of the superconducting elements, and
   ii. a transition temperature of the superconducting material of the one or more conductors.

A possible advantage may be that this method enables depositing the superconducting material of both the superconducting elements and the conductors as the same material and/or in the same step. This may be beneficial for a fast, cost-effective and/or efficient manufacturing process. The transition temperatures of the superconducting elements and the conductors may be similar, such as substantially identical, such as identical prior to the second step. A difference in transition temperature may be created (such as in case the transition temperatures were identical before the second step) and/or an increased (such as in case there was a difference in transition temperatures before the second step) during the second step. A difference in transition temperature (T_{c}) between the superconducting elements and the conductors after the second step may be at least 0.1 K, such as at least 1 K, such as at least 10 K, such as at least 20 k, such as at least 50 k. After the second step, the transition temperature of the superconducting elements may be higher than the transition temperature of the conductors.

### BRIEF DESCRIPTION OF DRAWINGS

The first, second, third, fourth and fifth aspect according to the invention will now be described in more detail with regard to the accompanying figures. The figures show one way of implementing the present invention and is not to be construed as being limiting to other possible embodiments falling within the scope of the attached claim set.

FIG. 1 is a schematic perspective illustration of a tape with superconducting elements.

FIG. 2 shows an image of an element comprising a substrate with superconducting elements thereon, such as superconducting pixels, which element could correspond to a part of a tape.

FIG. 3 shows is a schematic illustration showing the details of each meander structure.

FIG. 4 shows images of meander structures of a superconducting thin film deposited on a tape structure.

FIG. 5 shows schematic illustrations of three possible ways of electrically connecting the superconducting elements

FIG. 6 shows raw data for response measured for a neutron signal using an element as shown in FIG. 2.

FIG. 7 shows a response measured using an element as shown in FIG. 2 for an incident laser beam.

FIG. 8 shows further data showing that an amplitude of the signal is significantly reduced without absorbing layer.

FIG. 9 shows a setup applicable for obtaining the data of FIG. 6, FIG. 7 and FIG. 8.

FIG. 10 shows a photo of the straining of a thin HTS strip coated with a layer of ¹⁰B₄C.

FIGS. 11-14 show different arrangements of the tape including substrate.

FIG. 15 shows a cross-sectional view of a plane through a part tape 1500 with a pixel tilted out of the of remaining tape.

FIG. 16 illustrates in a schematic manner the configurations employed for obtaining the data of FIG. 17.

FIG. 17 shows data obtained for tilting a superconducting element to different angles.

### DETAILED DISCLOSURE OF THE INVENTION

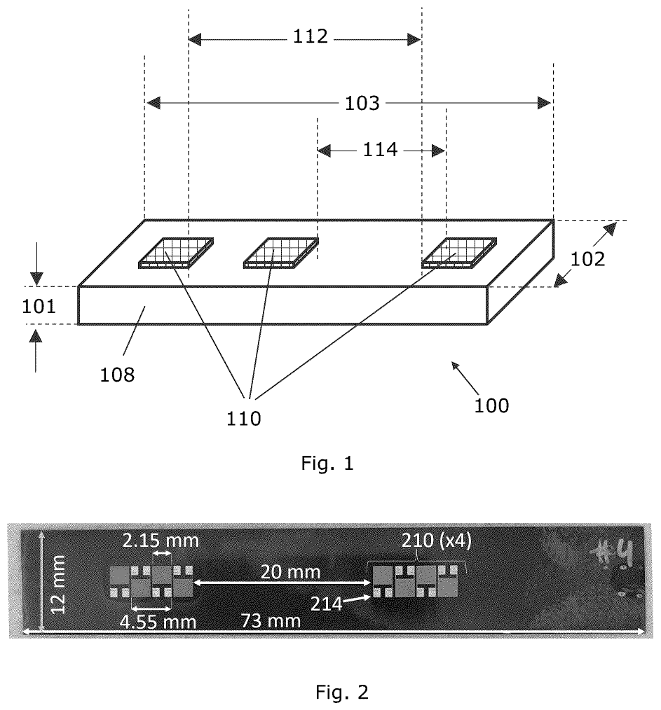

FIG. 1 is a schematic perspective illustration of a tape 100 comprising a plurality of superconducting elements 110, such as pixels, distributed along a longitudinal direction (i.e., the left/right direction in the plane of the paper) of the tape, wherein the tape has a size 101 along a first dimension (such as an up/down direction in the plane of the paper), such as a thickness, which is at least 10 times smaller, such as at least 100 times smaller, such as at least 1000 times smaller, than a size 102 along a second dimension (i.e., in a direction into/out-of the paper in the perspective illustration), such as a width, and where the size 102 along the second dimension, such as the width, is at least 10 times smaller, such as at least 100 times smaller, such as at least 1000 times smaller, than a size 103 along a third dimension (i.e., the left/right direction in the plane of the paper), such as a length. In the presently depicted embodiment, the tape comprises a substrate in the form of a rectangular cuboid, i.e., having no pillars, no through-going holes and no protrusions.

A distance 112 along the longitudinal direction of the tape between two superconducting elements being most distant with respect to each other (i.e., the left-most and the right-most in the present drawing) is at least 5 mm.

A nearest neighbor distance 114 along the longitudinal direction of the tape between two superconducting elements is at least 5 mm, such as at least 10 mm.

FIG. 2 shows an image of an element comprising a substrate with superconducting elements thereon, which element could correspond to a part of a tape. In the image (wherein a viewing direction is top-down, corresponding to a direction towards the substrate comprising superconducting elements from above and in a direction orthogonal to the plane of the substrate (corresponding to an up-down direction in FIG. 1). The total thickness (in a direction orthogonal to the plane of the paper) of the substrate is less than 60 μm. The width (in a direction up-down in the plane of the paper) is 12 mm, and a length (in a left-right direction in the plane of the paper) is 73 mm). The image shows a plurality of superconducting elements 210 (8 in total, arranged in two groups of 4), wherein each superconducting element comprises a portion shaped in a meander pattern. A square circumscribing each meander pattern has a side length of 2.15 mm. The image also shows that for each superconducting element, a contact pad 214 being separate from and electrically connected to the corresponding superconducting element is provided. The element has been provided by obtaining a coated conductor comprising a substrate with 50 μm Hastelloy C276, 2-3 μm buffer layer (e.g., with the buffer layer comprising, such as consisting of, one or more of Al₂O₃, Y₂O₃, MgO, Gd—Zr—O or SrTiO₃), 1 μm REBCO (such as GdBa₂Cu₃O₇) and 1-2 μm Ag, then removing a part of the silver (Ag) layer to form the (Ag) contact pads and uncover the superconductor elements and finally adding a 4 μm Boron carbide (¹⁰B₄C) as an absorbing layer on top of the superconductor elements.

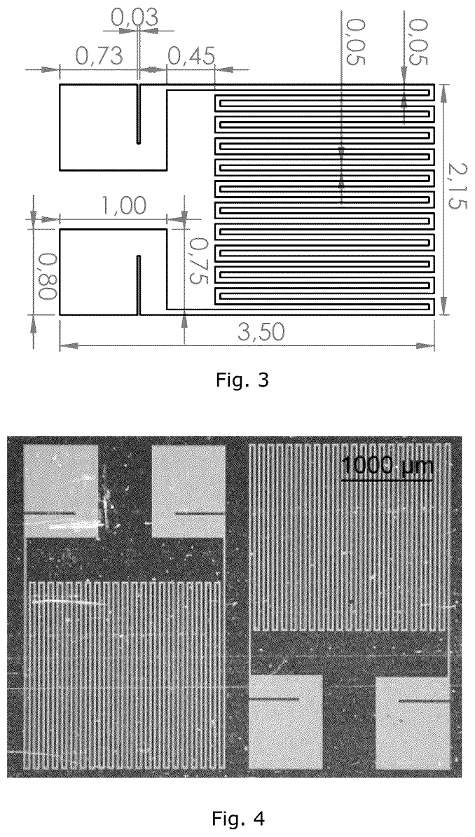

FIG. 3 shows is a schematic illustration showing the details of each meander structure including dimensions given in millimeters.

FIG. 4 shows images of meander structures including a 1000 μm scalebar.

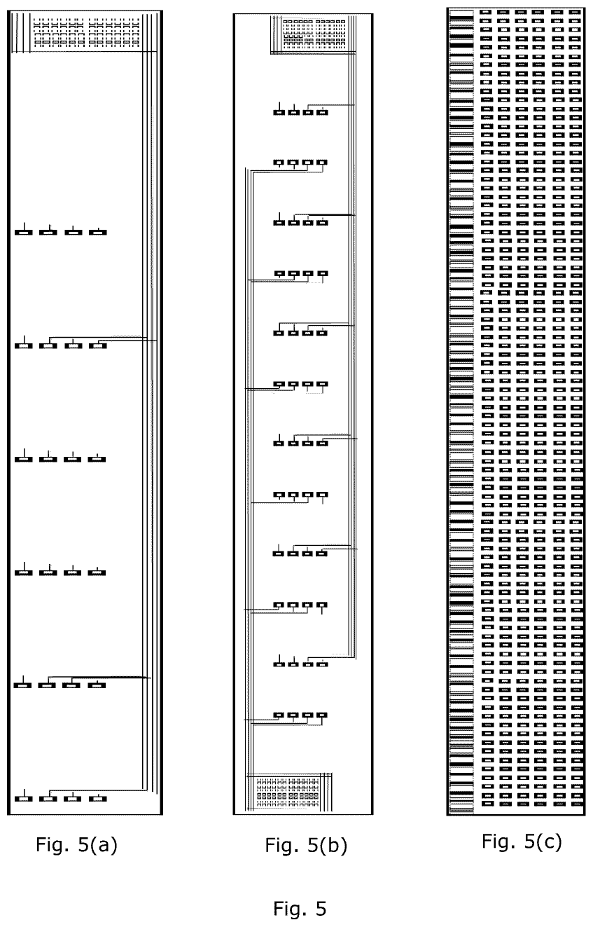

FIG. 5 shows schematic illustrations of three possible ways of electrically connecting the superconducting elements to enable electrically access them from a different position.

Subfigure (a) shows each superconducting element having a dedicated conductor extending from the superconducting element to one end of the tape. Each superconducting element may furthermore be electrically connected (not shown) to another conductor enabling forming a circuit, such as via another dedicated conductor or to a common (to all superconducting elements) conductor.

Subfigure (b) is similar to subfigure (a) except half the superconducting elements are electrically connected to the opposite end of the tape. This may be beneficial for having less connections, such as contact pads in one end (such as the upper end of the figure) of the tape.

Subfigure (c) shows each superconducting element having a dedicated conductor extending from the superconducting element to the side of the tape. This may be advantageous for having shorter conductors and/or for increasing a length along which the conductors can be accessed. According to an embodiment, multiple tapes of the type depicted in subfigure (c) may be mounted adjacent to each other, such as in a staircase rack, so as to cover together a larger area, and/or so as provide a more densely packed area of pixels.

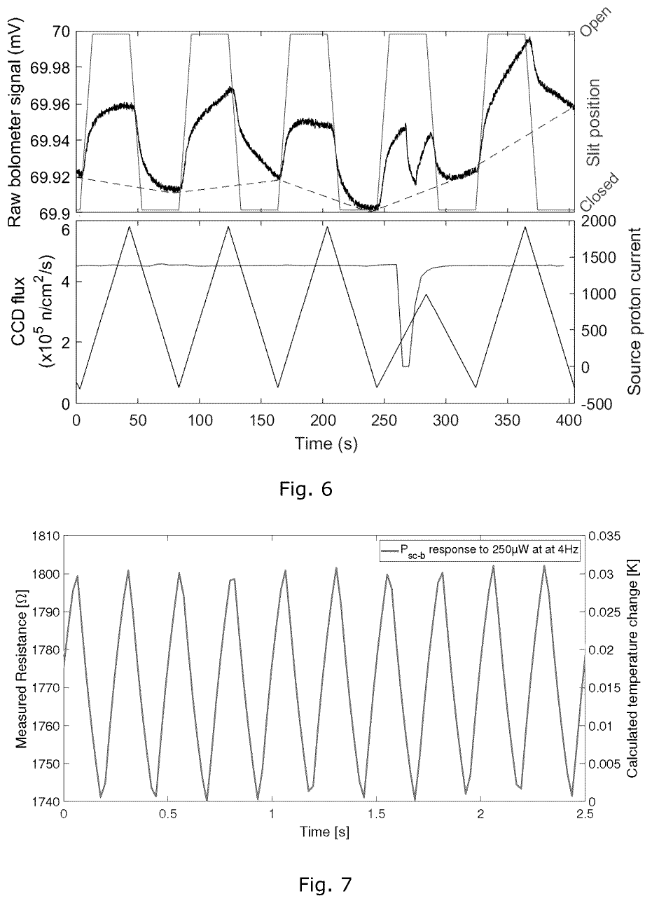

FIG. 6 shows raw data for response measured for a neutron signal using an element as shown in FIG. 9 (with one of the superconducting elements with absorbing layer, i.e., one of the upper three superconducting elements shown of the four superconducting elements in FIG. 9). The trapezoidal, grey curve in the upper graph shows the position of a slit blocking the neutrons. The black curve in the upper graph shows the raw bolometer signal. The triangular, black curve in the bottom graph is reference flux measured by a commercial detector, measured as an average over a half slit movement period. The grey curve in the bottom graph is the source proton current. The figure goes to show that detection, even quantitative detection, of particle radiation, in this case neutron radiation, is realized with an element corresponding to a section of a tape.

The raw bolometer signal saturates, which goes to indicate that even for increasing CCD flux, the structure is capable of conducting sufficient thermal heat away to avoid overheating. This may in turn be advantageous for ensuring longevity of the element.

The raw bolometer signal rises and falls with increasing and decreasing CCD flux, which goes to indicate that the element is suitable for repeated measurement and/or time-resolved measurements.

FIG. 7 shows a response measured using an element as shown in FIG. 9 (with the superconducting element without absorbing layer, i.e., the superconducting element shown as the lowest positioned superconducting element of the four superconducting elements in FIG. 9) for an incident laser beam with a wavelength of 633 nm (i.e., red visible laser light) and with 4 Hz modulation frequency obtained using an optical chopper. The figure goes to show that detection, even quantitative detection, of electromagnetic radiation, in this case visible light, is realized with an element corresponding to a section of a tape.

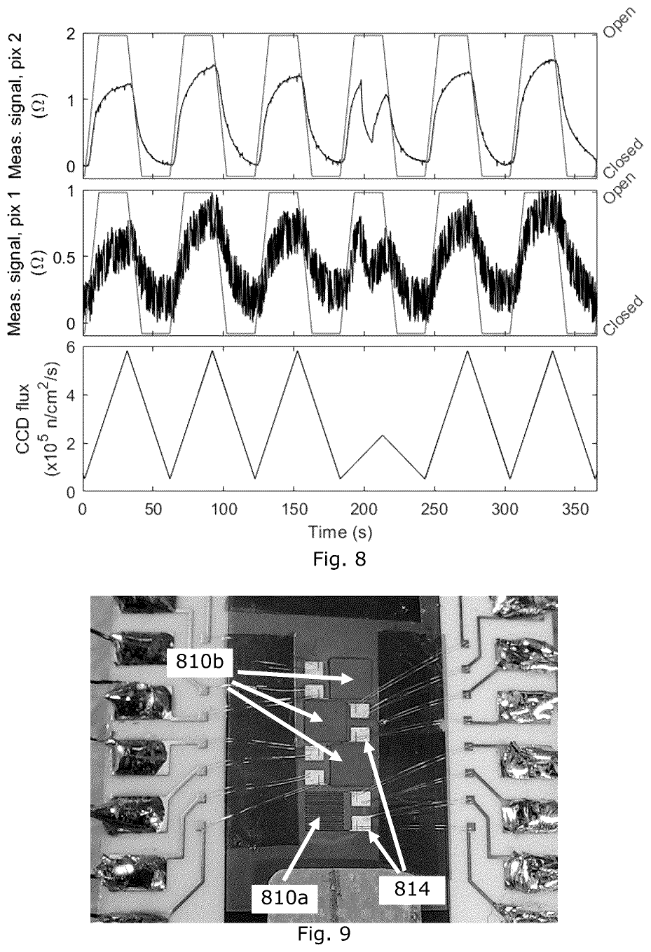

FIG. 8 shows data in the upper graph similar (albeit not identical) to the data in the upper graph of FIG. 6 and in the lower graph data being similar (albeit not identical) to the data in the lower graph of FIG. 6. Furthermore is shown data in the middle graph similar to data in the upper graph except it is obtained for a superconducting element not having an absorbing layer. In other words, the figure shows data measured with and without absorption layer. Pix 1 (middle) is without absorption layer, Pix 2 (top) is with absorption layer. Bottom graph is reference neutron flux measured by a commercial detector. The figure shows that an amplitude of the signal is significantly reduced without absorber. A part of the signal in the middle graph correlating with the neutron flux may be fully or partially due to thermal cross-talk (such as heat generated at an adjacent absorbing layer, such as at a superconducting element with an absorbing layer, cf., e.g., at one or more of superconducting elements 810b in FIG. 9, which is then carried via thermal conduction, to the superconducting element without the absorption layer, cf., e.g., superconducting element 810a in FIG. 9). Regarding the difference in noise level, a non-limiting interpretation is provided as follows: The absorbing layer (on Pix 2) acts as a thermal mass for the very sensitive superconducting circuit. The absorbing layer thereby acts as to dampen the thermal noise (such as the higher frequencies thereof relative to the thermal background variations) measured in the superconducting circuit. The superconducting circuit (associated with Pix 1, i.e., without absorbing layer) is more sensitive to small thermal variations (noise), such as due to the lower thermal mass in the absence of an absorbing layer. An alternative and/or additional origin of the difference in noise level may simply be coincidental differences in set-up, such as differences in wire-bonding, which may cause different circuits to pick up different levels of noise.

FIG. 9 shows a setup applicable for obtaining the data of FIG. 6, FIG. 7 and FIG. 8, wherein electrical connections to the superconducting elements is realized via contact pads 814 (with arrows only pointing to two out of 8 contact pads) and wire bonding. It is in particular noted that the three upper superconducting elements 810b (which could each correspond to “Pix 2″ in FIG. 8) is covered with an absorbing layer, whereas the lower superconducting element 810a (which could correspond to ”Pix 1″ in FIG. 8) is not covered with an absorbing layer.

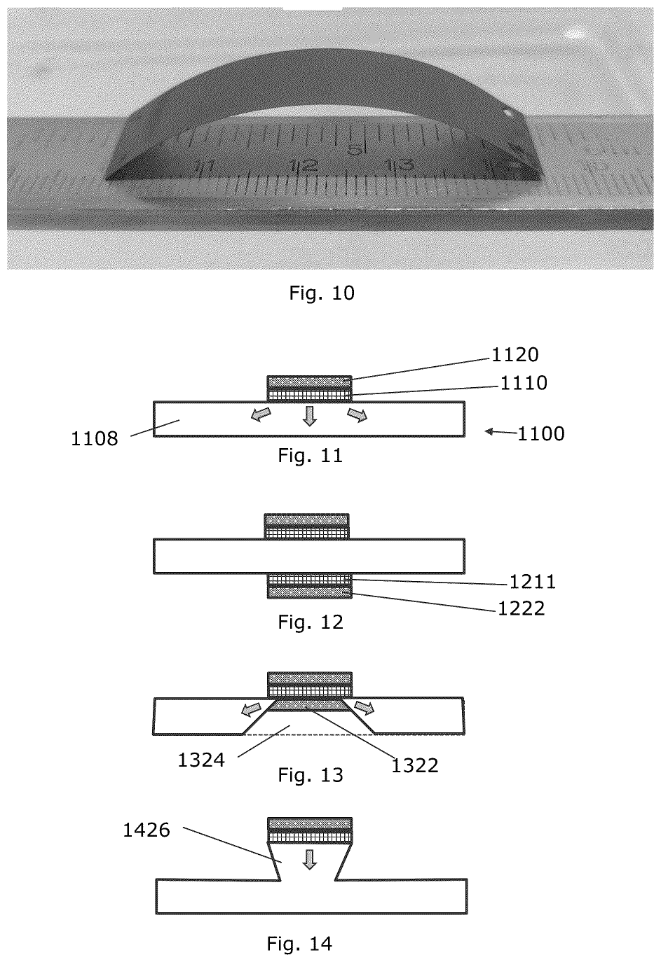

FIG. 10 shows a photo of the straining of a HTS strip, which was coated with 4 μm a ¹⁰B₄C on the side of the tape with a REBCO layer facing outwards. Data (not shown) confirms that it was still superconducting at 77 K and with stable material properties, such as T_{c} and/or J_{c}, remaining stable, such as deviating for less than 10 %. A radius of curvature as measured from the bottom of the sample is approximately 34 mm. HTS tapes can be provided, which can be bend to a radius of curvature of, e.g., 10 mm without degrading the superconducting properties, see for example the article “Bending radius limits of different coated REBCO conductor tapes—an experimental investigation with regard to HTS undulators”, Richter et al., 12^{th} International Particle Accelerator Conference (IPAC 2021), May 24-28 2021, Brazil, pp. 3837-3840, 2021, and/or the article “Bending properties of different REBCO coated conductor tapes and Roebel cables at T=77 K”, Simon Otten et al., Supercond. Sci. Technol. 29 125003, 2016, where each of the two references is hereby included by reference in entirety.

FIGS. 11-14 show different arrangements of the tape including substrate. Each figure shows a cross-sectional view of a plane through the tape being orthogonal to the longitudinal direction and intersecting a superconducting element.

FIG. 11 shows a tape 1100 comprising a substrate 1108 being a rectangular cuboid, a superconducting element 1110 and an absorbing layer 1120. The thick, grey arrows indicate that heat can be dissipated away from the superconducting element 1110 in multiple directions through the substrate.

FIG. 12 shows a tape similar to the tape of FIG. 11, except that a superconducting element 1211 and an absorbing layer 1222 has been added to the opposite side of the substrate with respect to the superconducting element in FIG. 11, yielding a tape wherein the substrate is sandwiched by superconducting elements on each side, and wherein on the distal side of each superconducting element with respect to the substrate an absorbing layer is placed.

FIG. 13 shows a tape similar to the tape of FIG. 11, except that a part of the substrate below the superconducting element has been removed leaving a hole 1324 directly below the superconducting element (but not in the full length of the tape as indicated by the dashed line at the bottom of the substrate). The thick, grey arrows indicate that heat can be dissipated away from the superconducting element in multiple directions through the substrate, yet not in the directly downward direction, i.e., less heat can be dissipated as compared to the embodiment of FIG. 11. The figure furthermore shows an additional absorbing layer 1322 placed on the (lower) other side of the superconducting element with respect to the superconducting element placed on the upper side of the superconducting element.

FIG. 14 shows a tape similar to the tape of FIG. 11, except that a pillar 1426 has been placed directly below the superconducting element. The thick, grey arrow indicate that heat can be dissipated away from the superconducting element through the substrate, yet only directly downward, i.e., less heat can be dissipated as compared to the embodiment of FIG. 11. The pillar is provided with undercuts, which may go to further enhance an effect of diminishing the heat conduction through the pillar.

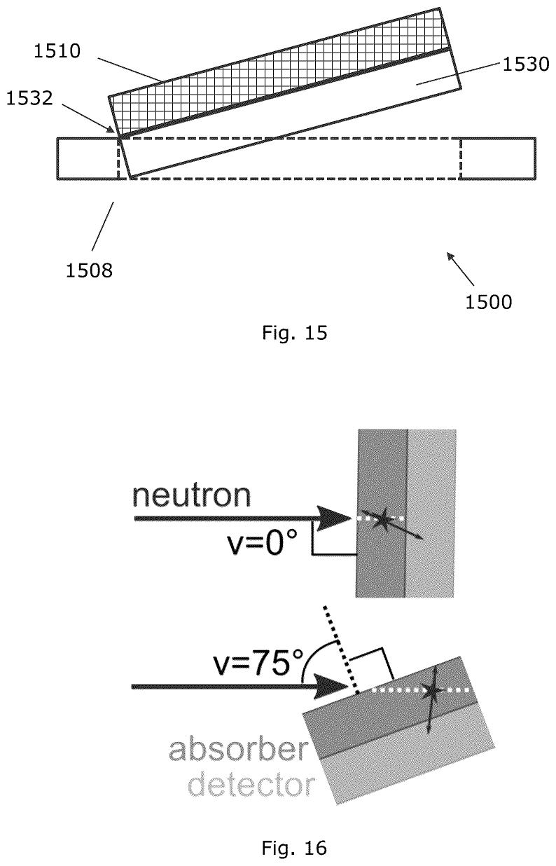

FIG. 15 shows a cross-sectional view of a plane through a part tape 1500 being parallel with each of a longitudinal direction of the tape and a normal vector to a plane of the tape and intersecting a superconducting element 1510. A part of the substrate 1530 has been released while still remaining hinged at a point 1532 to the remainder of the substrate 1508, so as to enable tilting of the superconducting element.

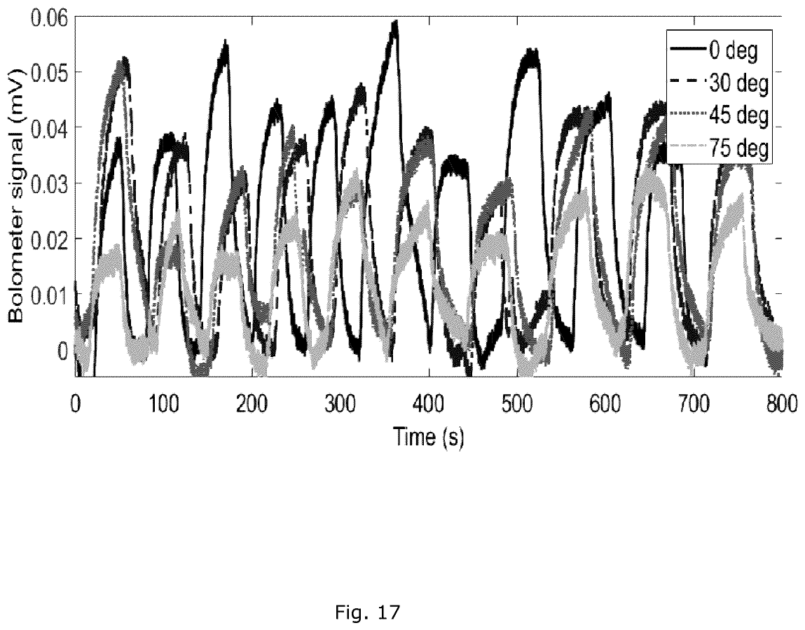

FIG. 17 shows data obtained for tilting a superconducting element to different angles. The figure shows that tilting significantly modifies the amplitude of the signal, cf., e.g., the peaks of the signal obtained for 0°are consistently higher than for the signal obtained for 75°.

According to an embodiment, the tape is bent (e.g., to conform to a shape of another element, such as an inside of a fusion reactor), yet the superconducting elements are tilted, e.g., so as to negate the angle (e.g., between a normal vector of the tape and incident radiation) otherwise introduced by the bending for at least some of the superconducting elements. In a particular embodiment, the tape is shaped to form a hemisphere or a sphere with a center substantially coinciding with a radiation source, and one or more superconducting elements are tilted so as to exhibit a smaller angle between a surface normal of the superconducting elements and the incident radiation compared to an angle between a surface normal of adjacent tape and incident radiation.

FIG. 16 illustrates in a schematic manner the configurations employed for obtaining the data of FIG. 17.

### Example (1) of Fabrication Method

Fabrication of a tape, such as a composite tape-based detector, may entail multiple fabrication steps which are all large scale and industrially applicable using one or more reel to reel processes. The steps used to make the detector units presented in FIG. 2 and FIG. 9 includes: substrate electropolishing, buffer and REBCO layer deposition, metallic protection layer deposition, REBCO layer patterning by UV lithography, pattern etching, absorbing layer deposition and final wiring.

Substrate reel to reel electropolishing of cold rolled 0.050 mm×12 mm Hastelloy C276 tape of several meters length, is performed in a heated (40-70° C.) mixture of sulfuric and phosphoric acid applying an appropriate direct current (100-1000 mA/cm²) between the tape and to one or more opposite placed electrodes for several minutes to obtain a smooth substrate surface.

Buffer reel to reel layer deposition can be conducted using an alternating beam deposition, or ion beam assisted deposition, of either MgO (˜10-30 nm layer thickness) or Yttrium-Stabilized-Zirconium (YSZ, ˜1-2 μm layer thickness) with an ion beam applied at an angle of 55° incident on the tape surface, i.e. at angle respective to the rolling-transverse plane of the substrate, such as to allow for strong texturizing of the buffer layer. The textured buffer layer is further coated, with an additional layer such as CeO₂ to provide improved lattice matching coefficients between the buffer layer stack and the subsequent adjacent REBCO layer.

REBCO reel to reel layer deposition (such as YBa₂Cu₃O₇₋ₓ or GdBa₂Cu₃O₇₋ₓ, or a mixture (Gd, Y)Ba₂Cu₃O₇₋ₓ) with a thickness of e.g. 100 nm, or 1 μm, is conducted using pulsed laser deposition or metal organic chemical vapor deposition at an elevated temperature between 600 and 1000° C. The REBCO layer is subsequently coated with a protective 1-2 μm layer of Ag by sputtering or e-beam deposition. An oxygenation step, where the Ag-coated stack is heated to above 250° C. and subjected to oxygen gas, is included to increase the oxygen content in the REBCO layer and thereby provide a superconducting structure.

Meander patterning is conducted by applying a photoresist on top of the Ag layer and baking it at 100-120° C. for several minutes. The photoresist is then exposed to UV light through a meander patterned master, e.g., using a continuous process in between 10-60 seconds, where the photoresist-coated HTS tape is rolled around a rotating large area glass cylinder with meander geometry and a central UV light source.

Developing of the meander structure, see FIGS. 3 and 4, is then conducted by subjecting the exposed photo-resist-coated tape to a developer solution, such as dilute sodium or potassium carbonate solution, which is heated to 20-50° C., for a period of for example 10-100 seconds. The resulting photoresist coverage now follows the structure provided by the meander patterned master, see FIG. 3.

Etching of the meander structure into the REBCO and Ag layers, as shown in FIG. 4, can be obtained chemically in two steps. Firstly, the unprotected (not covered by photoresist) part of the Ag layer is subjected to an agitated diluted nitric acid mixture (such 5-30 %) at 20° C. for 5-50 seconds or into an agitated mixture of NH₃OH (10%), H₂O₂ (10%) and water for several minutes at 20° C., until the unprotected part of Ag layer is removed, followed by rinsing in water and careful drying to protect the REBCO. It is noted that the REBCO layer may be harmed by excessive exposure to water.

REBCO etching is conducted in a diluted mixture of phosphoric acid and water (such as 1:100, such as 0.01 M) at 20° C. for several minutes until the meander pattern is fully etched into the REBCO layer. Alternative solutions with cerium ammonium nitrate can also be applied. The two etching steps can also be applied with each their successive photoresist layers.

The photoresist is then stripped in for example acetone for a few minutes or another suitable stripping agent, which is not harmful to the REBCO and Ag layers. Contact pads are then protected (such as covered with e.g. photoresist applying another series of lithographic step as shown above or alternative by a protective adhesive polymer tape, such as Kapton tape, in a reel to reel system) and the Ag layer on the meander pattern part of FIG. 3 is removed in an agitated mixture of NH₃OH (10%), H₂O₂ (10%) and water for several minutes and followed by a water rinse and careful drying. The protective (contact pads) photoresist (or adhesive tape) may be stripped or peeled.

A neutron sensitive absorbing layer, in this case, a boron carbide (¹⁰B₄) coating, is applied using direct-current magnetron sputtering and a mechanical mask shadowing all of the patterned tape except for the areas with pixels, such as a metal-based template that only allows deposition at the meander patterned pixel, see FIG. 3, and not the contact pads, nor the wiring, as shown in FIG. 2. The boron carbide coating can be applied as is done in the section “B. ¹⁰B₄C Deposition” of the article “Strain Effects of Absorbing Layer on Superconducting Properties of a High-Flux Neutron Detector”, Brock et al., IEEE Transactions on Applied Superconductivity, vol. 32, no. 4, June 2022, which section in particular and article in entirety is hereby included by reference.

### Example (2) of Fabrication

Fabrication of a tape wherein one or more of the superconducting elements within the plurality of superconducting elements (100) defines a plane which is non-parallel, such as is angled with at least 1° with respect to a plane of the tape, such as with respect to a plane defined by a portion of the tape being adjacent, such as adjoining, each of the one or more superconducting elements, such as a composite tape detector with tilted superconducting elements, such as part of the superconducting elements comprising a meander structure, may entail multiple fabrication steps, which are all large scale and industrially manufacturable. The steps applicable for producing said tape detector with tilted superconducting elements include: Electropolishing of the substrate, deposition of buffer and superconducting stack, UV lithography steps of: the meander pattern including in-plane wiring and/or contact pads and/or electrical wiring masking and superconducting elements periphery framing line (excluding a hinge area, or line, that includes the electrical connection enabling electrical addressability) and including etching of said structures and/or geometries. Finally, the superconducting elements can be physically tilted out of the substrate plane as shown in FIG. 15.

Process steps from Example (1) are performed from electropolishing of the substrate and to the process step including meander pattern and stripping of the photoresist to produce superconducting meander structures not covered with an absorber material.

Framing lines: A new layer of photoresist is applied to the tape now comprising patterned superconducting structures. The photoresist is exposed to UV light through a master (mask with a structure, such as a framing line, that the surrounds the periphery of the meander) that allows exposure of a line, with a line width of e.g., 100 μm, that surrounds the periphery of the superconducting elements. These lines must be framing each local meander patterns individually, such as framing the superconducting pixels individually, except for the part that connects the meander pattern to the contact pads and/or remaining electrical connection on the remainder of the tape. Development of the photoresist is conducted as described in Example (1). The area pertaining (part of, such as not including the area where the electrical connections are positioned) the periphery of superconducting that is not covered by photoresist is then etched, e.g. in a mixture of sulphuric acid and phosphoric acid at a temperature between 40-70° C., this may take up to several minutes, such as one hour, to etch all the way through the tape structure including the substrate, i.e. all material is etched so as to produce a hole through the lines that frames the peripheries excluding the hinge areas, such as the area including the electrical wiring to connect the superconducting element.

The tape structure is then stripped from photoresist and coated with an absorbing layer as described in Example (1).

The flaps, such as areas, that includes the superconducting elements, such as the pixels, are physically tilted out of the substrate plane by carefully, such as by physically pushing with a few Newton of force (e.g. 1-10 N using a tweezer), such as mechanically pushing the said areas, i.e. the flaps, around the hinge part of the tape structure as shown in FIG. 15, e.g., to an angle suitable for optimal detection. The pushing can be automated in a rolling system that includes a roll with local angled protrusions can carefully push out the flaps in a reel-to-reel manner.

### Example (3) of Fabrication

Fabrication of a tape wherein the tape comprises a substrate and wherein the substrate comprises protrusions, through-going holes and/or pillars at the positions of the superconducting elements, optionally with undercuts, such as a composite tape detector with pillar structured superconducting elements, such protrusions, such as part of the superconducting elements comprising a meander structure that is partly disconnected from the remaining tape structure, that is the element is displaced orthogonally from the remaining tape plane as shown in FIG. 14, may entail multiple fabrication steps which are all large scale and industrially applicable.

The substrate is electropolished as described in Example (1) and 3D structured as then produced as described in the patent application WO2013/174380A1 by Wulff, which is hereby included by reference in its entirety.

More specifically, the substrate can be modified following UV lithography steps, as described in Example (1), with respect to applying a photoresist, exposing to UV light through a master, developing the photoresist. Pillars are then produced on the substrate as the remainder of the substrate is electropolished, such as electro-etched, while areas specified for superconducting elements, such as pixels, are protected from electropolishing creating the structure presented in FIG. 14.

### Example (4) of Fabrication

Fabrication of the composite tape detector with reduced local substrate thickness under, and/or surrounding the structured superconducting elements may entails multiple industrially applicable fabrication steps. The main part of the substrate can be protected with photoresist, such as by following the UV lithography steps described in Example (1), followed by local area etching from the backside of the substrate prior to, or after, deposition of the superconducting stack, such as a REBCO stack including a buffer layer stack, to provide the structure shown in FIG. 13.

Although the present invention has been described in connection with the specified embodiments, it should not be construed as being in any way limited to the presented examples. The scope of the present invention is set out by the accompanying claim set. In the context of the claims, the terms “comprising”or “comprises”do not exclude other possible elements or steps. Also, the mentioning of references such as “a” or “an” etc. should not be construed as excluding a plurality. The use of reference signs in the claims with respect to elements indicated in the figures shall also not be construed as limiting the scope of the invention. Furthermore, individual features mentioned in different claims, may possibly be advantageously combined, and the mentioning of these features in different claims does not exclude that a combination of features is not possible and advantageous.

### Clauses

There is furthermore presented a tape comprising a plurality of superconducting elements, a bolometer and/or a kinetic inductance detector comprising the tape, a system comprising the tape, use of the tape and a method of providing the tape according to the clauses below, which clauses may be combined with any of the preceding embodiments and/or any of the appended claims:
1. A tape (100) comprising a plurality of superconducting elements (110), such as pixels, distributed along a longitudinal direction of the tape, wherein the tape has
   a size (101) along a first dimension, such as a thickness, which is at least 10 times smaller, such as at least 100 times smaller, such as at least 1000 times smaller, than a size (102) along a second dimension, such as a width,
   and where
   the size (102) along the second dimension, such as the width, is at least 10 times smaller, such as at least 100 times smaller, such as at least 1000 times smaller, than a size (103) along a third dimension, such as a length.
2. The tape (100) according to any of the preceding clauses, wherein a distance (112) along the longitudinal direction of the tape between two superconducting elements being most distant with respect to each other is at least 5 mm, such as at least 10 mm, such as at least 50 mm, such as at least 100 mm, such as at least 500 mm, such as at least 1 m, such as at least 5 m, such as at least 10 m, such as at least 50 m, such as at least 100 m, such as at least 1 km.
3. The tape (100) according to any of the preceding clauses, wherein a nearest neighbor distance (114) along the longitudinal direction of the tape between two superconducting elements is at least 5 mm, such as at least 10 mm, such as at least 50 mm, such as at least 100 mm, such as at least 500 mm, such as at least 1 m, such as at least 5 m, such as at least 10 m, such as at least 50 m, such as at least 100 m, such as at least 1 km.
4. The tape (100) according to any of the preceding clauses, wherein the tape is furthermore comprising one or more conductors, such as superconducting conductors, such as HTS conductors, enabling electrically addressing one or more individual superconducting elements (110) from a position spaced apart from each of the one or more individual superconducting elements in a direction along the longitudinal direction of the tape, such as spaced apart in the longitudinal direction by at least 1 cm, such as at least 10 cm, such as at least 1 m, such as at least 10 m, such as at least 100 m, such as at least 1 km.
5. The tape (100) according to any of the preceding clauses, wherein a transition temperature of one or more of the superconducting elements (110) is:
Within ]275 K; 255 K[, such as ]270 K; 260[, such as 265 K,
Within ]150 K; 170 K[, such as ]155 K; 165 K[, such as 160 K,
Within ]120 K; 140 K[, such as ]125 K; 135 K[, such as 130 K,
Within ]100 K; 120 K[, such as ]105 K; 115 K[, such as 110 K,
Within ]81 K; 101 K[, such as ]86 K; 96 K[, such as 91 K,
Within ]80 K; 100 K[, such as ]85 K; 95 K[, such as 91 K,
Within ]67 K; 87 K[, such as ]72 K; 82 K[, such as 77 K,
Within ]40 K; 60 K[, such as ]45 K; 55 K[, such as 50 K,
Within ]20 K; 40 K[, such as ]25 K; 35 K[, such as 30 K,
Within ]10 K; 30 K[, such as ]15 K; 25 K[, such as 20 K,
Within ]2.2 K; 6.2 K[, such as ]3.2 K; 5.2 K[, such as 4.2 K,
Within ]1 K; 3 K[, such as ]1.5 K; 2.5 K[, such as 2 K, or
Within ]0 K; 1 K[, such as ]50 mK; 200 mK[, such as 100 mK.
6. The tape (100) according to any of the preceding clauses, wherein the plurality of superconducting elements (110) distributed along a longitudinal direction of the tape is 4 or more, such as 5 or more, such as 10 or more, such as 50 or more, such as 100 or more, such as 500 or more, such as 1000 or more, such as 10000 or more.
7. The tape (100) according to any of the preceding clauses, wherein the tape comprises a radiation absorbing layer (1120), and wherein the radiation absorbing layer comprises, such as comprises at least 10 % w/w, such as substantially consists of, such as consists of, one or more of ³He, ⁶Li, ¹⁰B, ¹⁵⁷Gd and ¹¹³Cd.
8. The tape (100) according to any of the preceding clauses, wherein each superconducting element is individually electrically addressable, optionally at least partially via a conductor being superconducting, with respect to the other superconducting elements, such as enabling spatially resolving in a longitudinal direction of the tape radiation incident on the tape.
9. The tape (100) according to any of the preceding clauses, wherein the tape can be bent, such as bent without breaking or rupturing, such as elastically bent, so that a radius of curvature becomes less than 1 m, such as less than 50 cm, such as less than 25 cm, such as less than 10 cm, such as less than 5 cm, such as less than 20 mm, such as less than 10 mm, such as less than 5 mm, such as so that a radius of curvature changes between a region of less than 10 mm, such as less than 5 mm, and, such as to or from, a region being more than 100 mm, such as more than 1 m.
10. The tape (100) according to any of the preceding clauses, wherein one or more of the superconducting elements within the plurality of superconducting elements (100) defines a plane which is non-parallel, such as is angled with at least 1°, such as angled with at least 5°, such as angled with at least 10°, such as angled with at least 20°, such as angled with at least 30°, such as angled with at least 40°, such as angled with at least 45°, such as angled with at least 60°, with respect to a plane of the tape, such as with respect to a plane defined by a portion of the tape being adjacent, such as adjoining, each of the one or more superconducting elements.
11. The tape (100) according to any of the preceding clauses, wherein the tape comprises a substrate (108) and wherein the substrate comprises protrusions, through-going holes (1324) and/or pillars (1426) at the positions of the superconducting elements (110), optionally with undercuts.
12. A bolometer and/or a kinetic inductance detector comprising the tape (100) according to any of the preceding clauses.
13. a system comprising:
A tape (100) according to any of clauses 1-11, wherein the tape is furthermore comprising for each superconducting element a contact pad, and
A socket comprising a plurality of terminals,
   wherein the plurality of contact pads enables electrically accessing each superconducting element individually via the contact pads by positioning the tape in the socket with the terminals electrically contacting the contact pads.
14. Use of a tape (100) according to any of clauses 1-11, a bolometer and/or a kinetic inductance detector according clause 12, and/or a system according to clause 13, for detection, such as spatially resolved detection, of radiation, such as neutron radiation, terahertz radiation and/or infrared radiation.
15. A method of providing a tape (100) according to any of clauses 1-11, a bolometer and/or a kinetic inductance detector according clause 12, and/or a system according to clause 13, said method comprising:
Depositing the plurality of superconducting elements (110).

1.-33. (canceled)

34. A tape comprising a plurality of superconducting elements distributed along a longitudinal direction of the tape, wherein the tape has
a size along a first dimension which is at least 10 times smaller than a size along a second dimension,
and where the size along the second dimension is at least 10 times smaller than a size along a third dimension.

35. The tape according to claim 34, wherein the longitudinal direction of the tape is a lengthwise direction of the tape.

36. The tape according to claim 34, wherein the longitudinal direction of the tape is a direction of the tape along its largest dimension.

37. The tape according to claim 34, wherein the first dimension is a thickness, the second dimension is a width, and the third dimension is a length.

38. The tape according to claim 34, wherein the plurality of superconducting elements are pixels.

39. The tape according to claim 34, wherein the superconducting elements within the plurality of superconducting elements are spatially separated with respect to each other by a finite distance measured in the longitudinal direction.

40. The tape according to claim 34, wherein a distance along the longitudinal direction of the tape between two superconducting elements being most distant with respect to each other is at least 5 mm.

41. The tape according to claim 34, wherein a distance along the longitudinal direction of the tape between two superconducting elements being most distant with respect to each other is at least 50 mm.

42. The tape according to claim 34, wherein a distance along the longitudinal direction of the tape between two superconducting elements being most distant with respect to each other is at least 1 m.

43. The tape according to claim 34, wherein a nearest neighbor distance along the longitudinal direction of the tape between two superconducting elements is at least 5 mm.

44. The tape according to claim 34, wherein the tape is furthermore comprising one or more conductors, enabling electrically addressing one or more individual superconducting elements from a position spaced apart from each of the one or more individual superconducting elements in a direction along the longitudinal direction of the tape.

45. The tape according to claim 44, wherein each conductor is superconducting and has a transition temperature being different from a transition temperature of each of the superconducting elements.

46. The tape according to claim 45, wherein each superconducting element forms a coherent superconducting structure with a conductor.

47. The tape according to claim 34, wherein a transition temperature of one or more of the superconducting elements is:
Within ]275 K; 255 K[,
Within ]150 K; 170 K[,
Within ]120 K; 140 K[, such
Within ]100 K; 120 K[,
Within ]81 K; 101 K[,
Within ]80 K; 100 K[,
Within ]67 K; 87 K[,
Within ]40 K; 60 K[,
Within ]20 K; 40 K[,
Within ]10 K; 30 K[,
Within ]2.2 K; 6.2 K[,
Within ]1 K; 3 K[, or
Within ]0 K; 1 K[,

48. The tape according to claim 34, wherein the plurality of superconducting elements distributed along a longitudinal direction of the tape is 4 or more.

49. The tape according to claim 34, wherein the plurality of superconducting elements distributed along a longitudinal direction of the tape is 5 or more.

50. The tape according to claim 34, wherein the plurality of superconducting elements distributed along a longitudinal direction of the tape is 50 or more.

51. The tape according to claim 34, wherein the tape comprises a radiation absorbing layer, and
wherein the radiation absorbing layer comprises such one or more of 3He, 6Li, 10B, 157Gd and 113Cd.

52. The tape according to claim 34, wherein each superconducting element is individually electrically addressable with respect to the plurality of other superconducting elements.

53. The tape according to claim 34, wherein the tape can be bent that a radius of curvature becomes less than 1 m.

54. The tape according to claim 34, wherein the tape can be bent so that a radius of curvature becomes less than 20 mm.

55. The tape according to claim 34, wherein one or more of the superconducting elements within the plurality of superconducting elements defines a plane which is non-parallel.

56. The tape according to claim 34, wherein the tape comprises a substrate and
wherein the substrate comprises protrusions, through-going holes and/or pillars at the positions of the superconducting elements.

57. The tape according to claim 34, wherein the tape comprises a substrate and wherein the substrate comprises:
protrusions with undercuts, and/or
pillars with undercuts
at the positions of the superconducting elements.

58. The tape according to claim 34, wherein each superconducting element comprises at least a portion shaped in a meander pattern.

59. The tape according to claim 34, wherein the superconducting elements each comprise a meander structure,
wherein a dimension of a line within the meander structure along the first dimension and/or the second dimension, is within [1 μm; 100 μm].

60. The tape according to claim 34, wherein the superconducting elements each comprise a meander structure
wherein a dimension of the meander structure along the first dimension, is within [50 nm; 5 μm].

61. A bolometer and/or a kinetic inductance detector comprising the tape according to claim 34.

62. A system comprising:
a tape according to claim 34, wherein the tape is furthermore comprising for each superconducting element a contact pad, and
a socket comprising a plurality of terminals,
wherein the plurality of contact pads enables electrically accessing each superconducting element individually via the contact pads by positioning the tape in the socket with the terminals electrically contacting the contact pads.

63. A method of providing a tape according to claim 34, said method comprising:
depositing the plurality of superconducting elements and/or depositing the superconducting material of the superconducting elements.

64. A method of providing a system according to claim 62, said method comprising:
depositing the plurality of superconducting elements and/or depositing the superconducting material of the superconducting elements.

65. The method according to claim 63, said method further comprising:
depositing one or more conductors enabling electrically addressing one or more individual superconducting elements from a position spaced apart from each of the one or more individual superconducting elements in a direction along the longitudinal direction of the tape.

66. The method according to claim 65, wherein the one or more conductors comprise superconducting material, and
wherein depositing the superconducting material of the superconducting elements and depositing superconducting material of the one or more conductors is carried out in a first step,
wherein in a second step being subsequent to the first step, one or both of
i. the superconducting material of the superconducting elements, and
ii. the superconducting material of the one or more conductors,
is treated so as to increase and/or introduce a difference in transition temperature, between
iii. a transition temperature of the superconducting material of the superconducting elements, and
iv. a transition temperature of the superconducting material of the one or more conductors.
